(19) United States
(12) Patent Application Publication
(10) Pub. No.: US 2011/0181234 A1
(43) Pub. Date: Jul. 28, 2011

(54) MOBILE MODULAR SOLAR POWER SYSTEM

(76) Inventor: Michael K. Branham, Sarasota, FL (US)

(21) Appl. No.: 13/078,245

(22) Filed: Apr. 1, 2011

Related U.S. Application Data
(60) Provisional application No. 61/319,979, filed on Apr. 1, 2010.

(51) Int. Cl. H01M 10/46; H01L 31/045; B23P 11/00; H01L 31/042

(52) U.S. Cl. 320/101; 136/245; 29/428; 136/244

(57) ABSTRACT

A portable modular solar power system generates electricity from sunlight to charge a battery and provide power to a load. Specifically, the portable system includes a load receiving the electrical power, and a portable modular solar power apparatus that includes a photovoltaic panel converting the sunlight to the electrical energy, a battery connected to the photovoltaic panel and receiving an electrical charge from the photovoltaic panel, and providing the electrical power to the load connected to the battery, and a lightweight frame housing the battery and having the photovoltaic panel connected thereto. The lightweight frame includes a battery tray supporting the battery and providing self ballasting for the portable modular solar power apparatus, and at least two adjustable telescoping legs providing support for the portable modular solar power apparatus and allowing for adjustments to an angle of the photovoltaic panel with respect to receipt of the sunlight.

### CROSS-REFERENCE

The present application claims priority to and incorporates by reference provisional application 61/319,979, filed Apr. 1, 2010.

### BACKGROUND OF THE INVENTION

1. Field of the Invention

The present invention generally relates to a portable modular solar power system that uses renewable energy obtained from sunlight to power an alternating current (AC) or direct current (DC) electrical system. In particular, the present invention relates to a portable modular solar power system that utilizes a solar panel to generate electricity from sunlight and to charge a battery to provide electrical power to an AC or DC electrical load.

2. Description of the Related Art

Photovoltaic panels have been widely used to generate electrical energy from sunlight. Photovoltaic panels are generally used in combination with batteries to provide electrical power to various electrical loads. However, conventional systems utilizing photovoltaic panels and batteries include large bulky structures that are not easily portable and expandable and do not use interchangeable and/or adjustable components. Furthermore, these conventional systems are not designed for rapid deployment or for use in extreme weather conditions.

Therefore, it would be useful to implement a rapidly deployable and portable modular solar power system for utilizing a solar panel in combination with a battery to provide electrical power to various electrical loads.

### BRIEF SUMMARY OF THE INVENTION

An embodiment of the invention is directed to a portable modular solar power apparatus for converting sunlight to electrical energy and providing electrical power to a load. The portable modular solar power apparatus includes a photovoltaic panel configured to convert sunlight to electrical energy, and a battery electrically connected to the photovoltaic panel thereby receiving an electrical charge from the photovoltaic panel and configured to provide the electrical power to the load electrically connected to the battery. Additionally, a lightweight frame is configured to house the battery and have the photovoltaic panel removeably attached thereto. The lightweight frame includes a battery tray configured to support the battery, wherein the battery also provides self ballasting for the portable modular solar power apparatus. The lightweight frame structure also includes at least two adjustable telescoping legs configured to provide support for the portable modular solar power apparatus and to allow for adjustments to an angle of the photovoltaic panel with respect to receipt of the sunlight.

Moreover, according to an embodiment of the invention each of the at least two telescoping legs is foldable to provide a fixed range of motion, such that, when the portable modular solar power apparatus is in an operational state, the at least two adjustable telescoping legs are folded out to provide support for the portable modular solar power apparatus. When the portable modular solar power apparatus is in a portable state, the at least two adjustable telescoping legs are folded in to decrease a size and increase mobility of the portable modular solar power apparatus.

An embodiment of the invention is also directed to a portable modular solar power system for converting sunlight to electrical energy and providing electrical power. The portable modular solar power system includes a load configured to receive the electrical power, and a portable modular solar power apparatus.

The portable modular solar power apparatus of the portable modular solar power system includes a photovoltaic panel configured to convert the sunlight to the electrical energy, a battery electrically connected to the photovoltaic panel thereby receiving an electrical charge from the photovoltaic panel, and configured to provide the electrical power to the load electrically connected to the battery. A lightweight frame is configured to have the photovoltaic panel removeably attached thereto and to house the battery. The lightweight frame includes a battery tray configured to support the battery, and to provide self ballasting for the portable modular solar power apparatus using the battery. At least two adjustable telescoping legs are configured to provide support for the portable modular solar power apparatus and to allow for adjustments to an angle of the photovoltaic panel with respect to receipt of the sunlight.

Additionally, each of the at least two telescoping legs is foldable to provide a fixed range of motion, such that, when the portable modular solar power apparatus is in an operational state, the at least two adjustable telescoping legs are folded out to provide support for the portable modular solar power apparatus, and when the portable modular solar power apparatus is in a portable state, the at least two adjustable telescoping legs are folded in to decrease a size and increase mobility of the portable modular solar power apparatus.

Moreover, the above-mentioned portable modular solar power system may include a second portable modular power apparatus. The second portable modular apparatus includes a second photovoltaic panel configured to convert the sunlight to the electrical energy, a second battery electrically connected to the second photovoltaic panel thereby receiving an electrical charge from the second photovoltaic panel, and configured to provide the electrical power to the load, and a second lightweight frame configured to have the second photovoltaic panel attached thereto and to house the second battery. The second lightweight frame includes a second battery tray configured to support the second battery, and to provide self ballasting for the second portable modular solar power apparatus using the second battery. At least two adjustable telescoping legs are configured to provide support for the second portable modular solar power apparatus and to allow for adjustments to an angle of the second photovoltaic panel with respect to receipt of the sunlight.

Also, according to an embodiment of the invention including the portable modular solar power system, the battery and the second battery can be connected in parallel, so as to increase a current of the electrical power provided to the load. Furthermore, the battery and the second battery can be connected in series, so as to increase a voltage of the electrical power provided to the load.

Another embodiment of the invention includes a method of assembling and using a portable modular solar power system for converting sunlight to electrical energy and providing electrical power to a load, wherein the portable modular solar power system includes the load configured to receive the electrical power and the portable modular solar power apparatus discussed above with reference to the previous embodiment.

This method of assembling and using the portable modular solar power system may include modularly connecting the photovoltaic panel to a lightweight frame and placing the battery on the battery tray of the lightweight frame, so as to provide support for the battery and self ballasting for the portable modular power apparatus using the battery, electrically connecting the photovoltaic panel and the battery so that the battery receives the electrical charge from the photovoltaic panel, electrically connecting the load to the battery allowing the load to receive the electrical power from the battery, and adjusting a length of the at least two adjustable telescoping legs, so as to provide the support for the portable modular solar power apparatus and to adjust the angle of the photovoltaic panel with respect to the receipt of the sunlight.

### BRIEF DESCRIPTION OF THE DRAWINGS

In the drawings, like reference numbers generally indicate identical, functionally similar and/or structurally similar elements. Embodiments of the invention will be described with reference to the accompanying drawings, wherein:

FIG. 1 illustrates a portable modular solar power apparatus for converting sunlight to electrical energy and providing electrical power to a load in accordance with an embodiment of the invention;

FIG. 2 illustrates a portable modular solar power system including two 230 watt portable modular solar power apparatuses with two 12 VDC batteries serially connected to provide a 460 watt solar array rated at 30.3 VDC in accordance with an embodiment of the invention;

FIG. 3 illustrates a portable modular solar power system including two of the 460 watt solar arrays, as illustrated in FIG. 2, each providing 30.3 VDC and connected in parallel to provide a total of 920 watts in accordance with an embodiment of the invention

FIG. 4 illustrates a portable modular solar power apparatus including a 130 watt solar power module and a 12 VDC battery in accordance with an embodiment of the invention;

FIGS. 5A-5C illustrate a physical structure of the specific portable modular solar power system including the 130 watt solar power module, as illustrated in FIG. 4, and a lightweight frame including telescoping legs and a battery tray in accordance with an embodiment of the invention;

FIG. 6 illustrates a portable modular solar power system including two 130 watt portable modular solar power apparatuses with two 12 VDC batteries connected in parallel to provide a 260 watt solar array rated at 17.4 VDC in accordance with an embodiment of the invention;

FIGS. 7A-7C illustrate a physical structure of a portable modular solar power system including a 230 watt solar panel in accordance with an embodiment of the invention; and

FIG. 8 illustrates a 5000 Watt DC Power Solar Bus providing 12/24/48 VDC to an electrical load.

Additional features are described herein, and will be apparent from the following description of the figures.

### DETAILED DESCRIPTION OF THE INVENTION

In the description that follows, numerous details are set forth in order to provide a thorough understanding of the invention. It will be appreciated by those skilled in the art that variations of these specific details are possible while still achieving the results of the invention. Well-known elements and processing steps are generally not described in detail in order to avoid unnecessarily obscuring the description of the invention.

In the drawings accompanying the description that follows, often both reference numerals and legends (labels, text descriptions) may be used to identify elements. If legends are provided, they are intended merely as an aid to the reader, and should not in any way be interpreted as limiting.

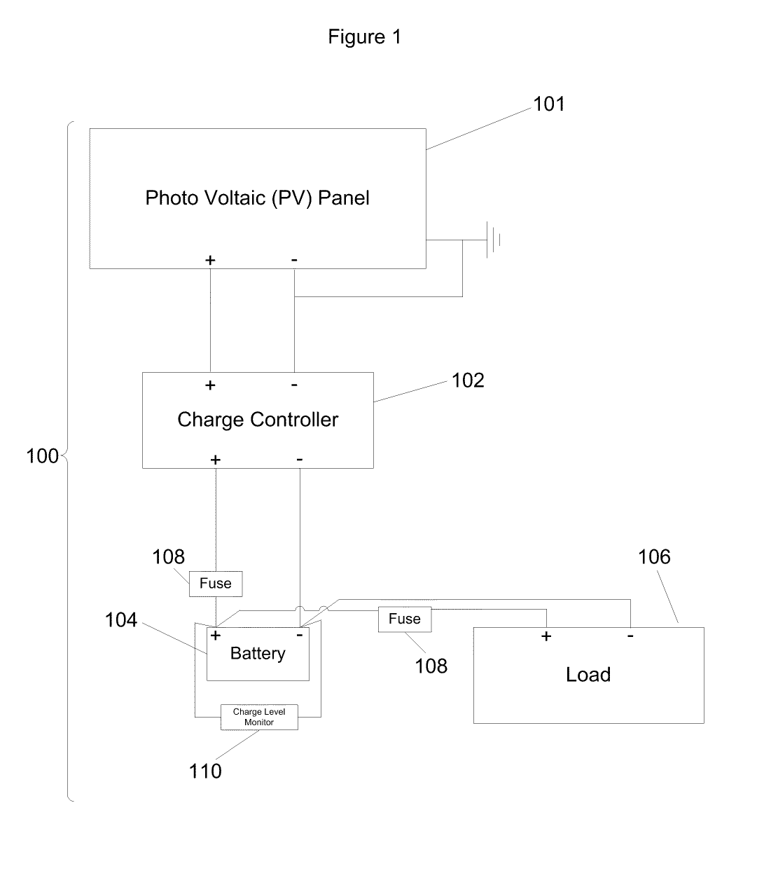

FIG. 1 is a portable modular solar power system for converting sunlight to electrical energy and providing electrical power. The portable modular solar power system includes a portable modular solar power apparatus 100 electrically connected to a load 106 and. The portable modular solar power apparatus 100 includes a photovoltaic (PV) panel 101, a charge controller 102, a battery 104, multiple fuses 108 and a charge level monitor 110. The PV panel 101 is, for example, a packaged interconnected assembly of solar cells, also known as photovoltaic cells. The solar cells can be crystalline silicon cells or thin-film cells, which can be rigid or flexible. More specifically, a photovoltaic panel from Sharp Electronics Corporation, model number NDU230C1, can be used as the PV panel 101, which will have a typical life cycle of 20 years.

The PV panel 101 is electrically connected to the charge controller 102, such that, when the PV panel 101 converts the received sunlight to the electrical energy, the charge controller 102 receives the electrical energy from the PV panel 101.

The charge controller 102 is capable of providing an electrical charge to the battery 104, based on the received electrical energy. Specifically, the charge controller 102 can be capable of controlling a charging rate of the battery based on, for example, a capacity of the battery 104, a drain on the battery 104 caused by the load 106, and an amount of electrical energy received from the PV panel 101. A typical charge controller from Morning Star Corporation, model number SS-20L-24V, can be used as the charge controller 102.

Further, the battery 104 is a rechargeable electrical power storage device and can be a gel cell, an absorbed glass mat, or a dry cell (e.g., nickel-cadmium, nickel-zinc, nickel metal hydride and lithium-ion) type battery. A typical marine grade gel cell battery rated at 12 VDC and 183 amp/hour or 12 VDC and 98 amp/hour can be used as the battery 104, which will typically have a life cycle of 5 years. The battery 104 is electrically connected to the charge controller 102, so as to receive the electrical charge from the charge controller and store electrical energy to be provided to the load 106. In addition, the load is electrically connected to the battery 104 in order to receive the electrical power from the battery 104.

The above-described portable modular solar power apparatus can be capable of providing the electrical power to a load 106 requiring alternating current (AC) power or direct current (DC) power. Furthermore, the portable modular solar power apparatus can be capable of providing, at least, 12 volt, 24 volt and 48 volt DC power, and can be capable of providing the AC power by utilizing a sine wave inverter.

The load 106 may include, for example, medical equipment, a remote communication system, a remote satellite up-link system, water purification, water pumping, a computer system, stationary refrigeration, mobile refrigeration, a battery charging station, and power tools.

The fuses 108 may be electrically connected between any of the PV panel 101, the charge controller 102, the battery 104 and the load 106 to provide electrical protection to the components of the portable modular solar power system during, for example, over current and under voltage conditions. As illustrated in FIG. 1, a fuse 108 is electrically connected between a positive terminal of the charge controller 102 and a positive terminal of the battery 104, and a fuse 108 is connected between a positive terminal of the battery 104 and a positive terminal of the load 106. The size and rating of the fuses will of course vary depending size and application of the portable modular solar power system. A charge level monitor 110 may also be connected to the positive and negative terminals of the battery 104, so as to provide a user with a simple way of monitoring the charge of the battery 104 as it receives a charge from the charge controller 102 and as the load 106 drains the charge of the battery 104 when providing the electrical power to the load 106.

Although many combinations of PV panels 101, batteries 104, charge controllers 102, etc., are possible, a few exemplary working models are described below. These exemplary working models are in no way intended to strictly limit the scope of the invention, but rather merely provide exemplary configurations of the above-described components.

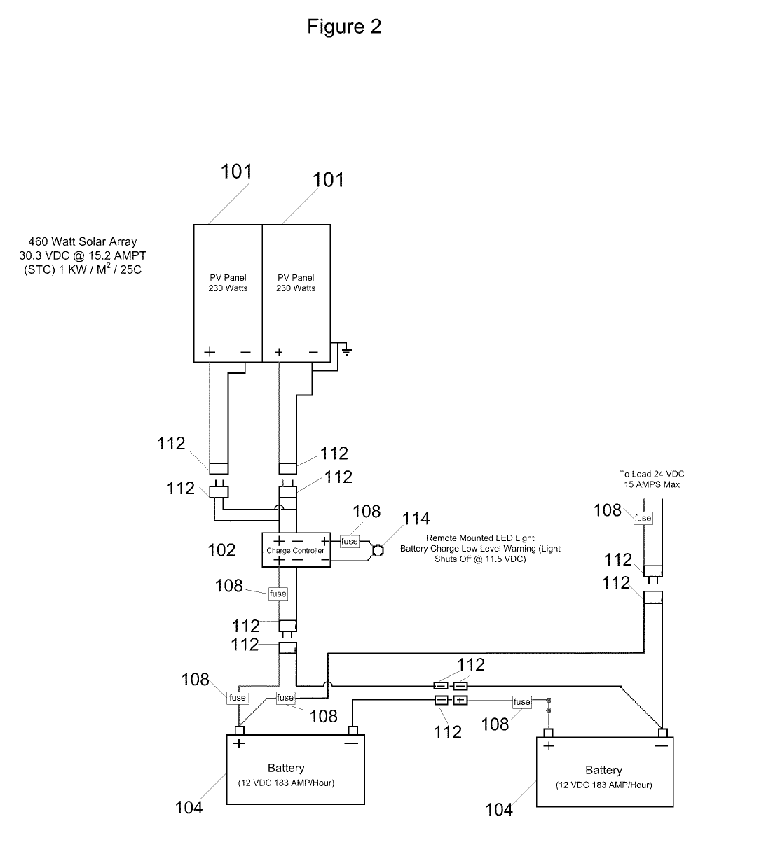

FIG. 2 illustrates a specific portable modular solar power system including two 230 watt portable modular solar power apparatuses having their respective 12 VDC batteries 104 connected in series, in order to increase a voltage of the electrical power provided to the load 106 and provide a 460 watt portable modular solar power system rated at 30.3 VDC. Specifically, the portable modular solar power system according to FIG. 2 includes two 230 watt PV panels 101. Each of the two 230 watt PV panels 101 is connected to the charge controller 102. The charge controller 102 has a remote mounted LED light 114 connected thereto with a fuse 108 located between the charge controller 102 and the LED light 114. The LED light 114 is used to indicate a low level of battery charge. For example, the LED light 114 may turn on after the battery 104 has reached a desired charge or may turn on if the charge of the battery 104 falls below a specific level.

Moreover, the charge controller 102 is connected to a first battery 104 and a second battery 104, such that a positive terminal of the first battery 104 is connected to a positive terminal of the charge controller 102 and a positive terminal of the load 106. The negative terminal of the first battery 104 is connected to a positive terminal of the second battery 104, such that the first and second batteries 104 are connected in series. The negative terminal of the second battery 104 is connected to the negative terminal of the charge controller 102 and the negative terminal of the load 106.

Moreover, fuses 108 are located between (i) the positive terminal of the first battery 104 and the positive terminal of the charge controller 102, (ii) the positive terminal of the first battery and the positive terminal of the load 106, and (iii) the negative terminal of the first battery 104 and the positive terminal of the second battery 104.

Also, quick connect plugs 112 are provided between the PV panels 101, the charge controller 102, the first battery 104, the second battery 104 and the load 106, allowing the electrical connections of the PV panel 101, the charge controller 102, the battery 104 and the load 106 to be quickly made or broken (see FIG. 2). These quick connect plugs 112 allow the user to quickly and easily add, remove and/or substitute any of the PV panels 101, the charge controller 102, the first battery 104, the second battery 104 and the load 106. Furthermore, the quick connect plugs 112 assist the user in obtaining a fast setup and break down and provide easy interchangeability of the various components of the portable modular solar power system. Additionally, these quick connect plugs 112 can include polarity identifiers so as to eliminate the possibility of the user incorrectly setting up (e.g., connecting the various components of) the portable modular solar power apparatus.

This above-describe working example illustrated in FIG. 2 provides 24 VDC at 15 amps maximum to the load 106 (more specifically, provides 30.3 VDC at 15.2 SMPT (STC) at 1 KW/M²/25 C).

More specifically, according to this working example or any of the following working examples, the PV panels 101 can be, for example, from Sharp Electronics Corporation (model number NDU230C1), the charge controller 102 can be from Morning Star Corporation (model number SS-20L-24V), and the battery 104 can be a marine grade deep cycle gel cell battery from Midstate Battery Incorporated (model 8G4D), which provides 12 VDC at 183 Amp/Hour.

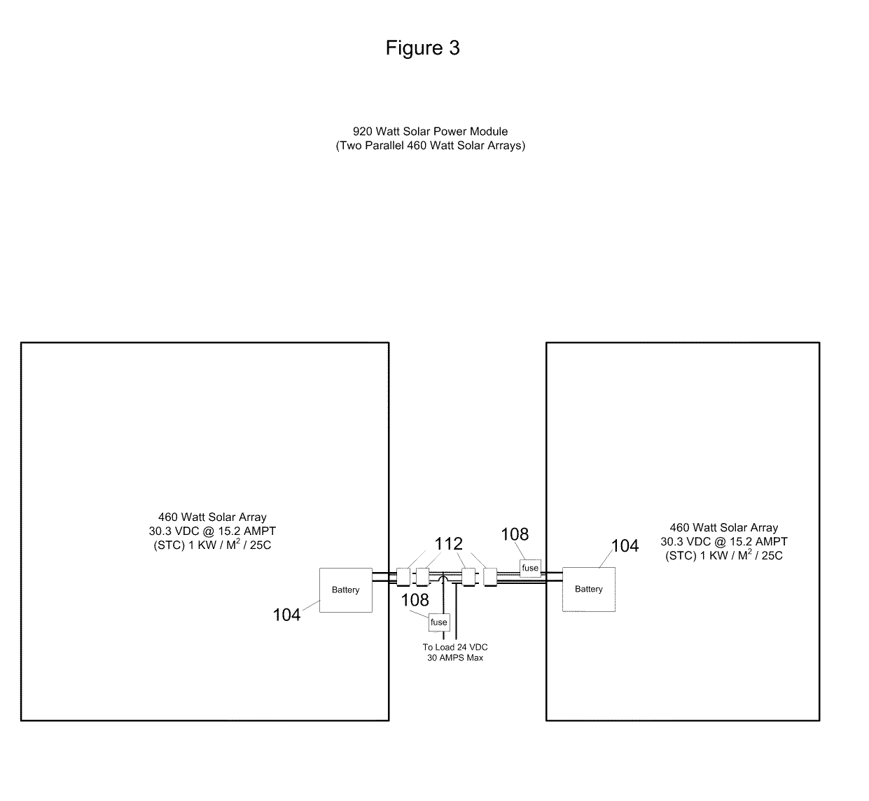

FIG. 3 illustrates a portable modular solar power system including two of the 460 watt solar arrays, as illustrated in FIG. 2, each providing 24 VDC (30.3 VDC) and connected in parallel to provide a total of 920 watts in accordance with an embodiment of the invention.

As illustrated in FIG. 3, a first battery 104 of a first 460 watt solar array is connected in parallel, via the quick connect plugs 112, to a second battery 104 of a second 460 watt solar array, so as to increase a current of the electrical power provided to the load 106. The load 106 is connected between the first battery 104 and the second battery 104. Fuses 108 are located between the first and second batteries 104 and the load 106. This configuration is capable of providing 920 watts to the load at 24 VDC and 30 amps maximum. Additional similar configurations can be utilized, for example, to obtain an electrical power of 1380 watts and 1840 watts.

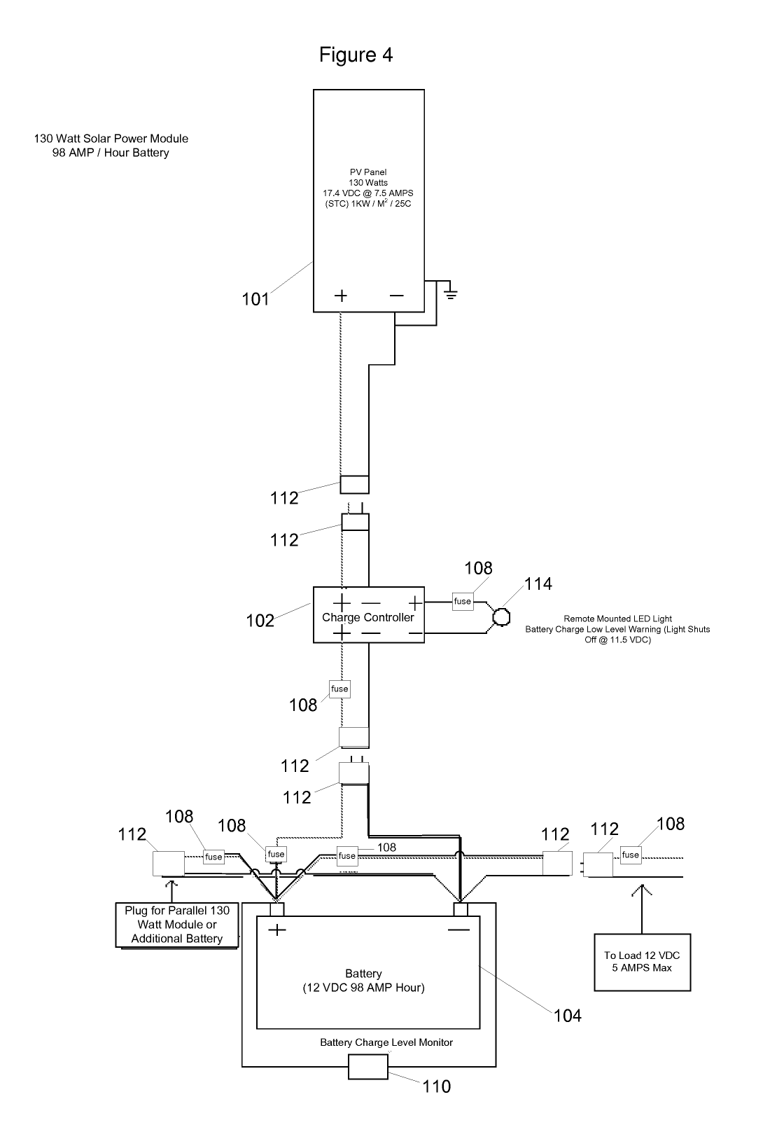

FIG. 4 illustrates a specific portable modular solar power system including a 130 watt solar power module and a 12 VDC battery 104 in accordance with an embodiment of the invention. Specifically, the portable modular solar power system according to FIG. 4 includes a single 130 watt PV panel 101, which is rated at 17.4 VDC at 7.5 amps (STC) 1 KW/M²/25 C. The 130 watt PV panel 101 is connected to the charge controller 102, via quick connect plugs 112. The charge controller 102 has the LED light 114 connected whereto with a fuse 108 between the charge controller 102 and the LED light 114. Moreover, the charge controller 102 is connected to a battery 104, such that a positive terminal of the battery 104 is connected to a positive terminal of the charge controller 102 and a positive terminal of the load 106, which receives 12 VDC and 5 amps maximum. The negative terminal of the battery 104 is connected to a negative terminal of the charge controller 102 and is connected to a negative terminal of the load 106. The battery 104 is connected to the charge controller 102 via quick connect plugs 112.

Moreover, fuses 108 are located between the positive terminal of the battery 104 and (i) the positive terminal of the charge controller 102, (ii) the positive terminal of the load 106, and (iii) a quick connect plug 112 for connecting to another 130 watt solar power module to be connected in parallel. Also, quick connect plugs 112 are provided between the battery 104 and the load 106. A battery charge level monitor 110 is also connected between the positive and negative terminals of the battery 104.

According to this working example, the battery 104 can be a marine grade deep cycle gel cell battery, which provides 12 VDC at 98 Amp/Hour.

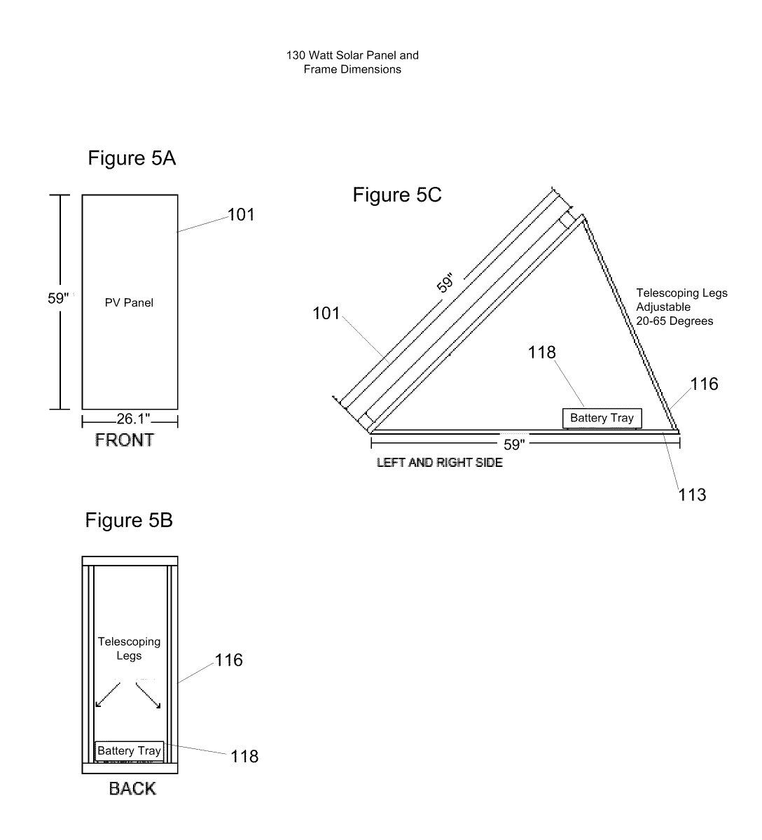

FIGS. 5A-5C illustrate a physical structure of the portable modular solar power apparatus including the 130 watt solar power module, as illustrated in FIG. 4, in accordance with an embodiment of the invention. FIG. 5A illustrates the front of the portable modular solar power apparatus, FIG. 5B illustrates the back of the portable modular solar power apparatus, when the portable modular apparatus is in a portable state, and FIG. 5C illustrates the left and/or right sides of the portable modular solar power apparatus, when the portable modular apparatus is in an operational state. Furthermore, even when in the portable state, the portable modular solar power apparatus can be capable of providing electrical power to the load 106.

The lightweight frame 113 includes a battery tray 118 configured to support the battery 104 (see FIGS. 5A and 5B), and includes at least two adjustable telescoping legs 116 (see FIGS. 5B and 5C). The battery tray 118 is configured to support the battery 104 and provide self ballasting for the portable modular solar power apparatus. The lightweight frame 133 also includes a top portion attached to the PV panel 101 and a bottom portion attached to the battery tray 118. The top portion and the bottom portion are movably attached at one end by a hinge member or the like (not shown). Furthermore, multiple batteries 104 can be stackable, so as to allow for minimum space consumption during transport of the portable modular solar power system/apparatus. Also, the multiple stacked batteries 104 can remain connected to the load 106 when the portable modular solar power apparatus is in the portable state, so as to allow the load 106 to continue to receive the electric power during any transportation thereof.

Additionally, as illustrated in FIG. 5C, the telescoping legs 116 of the portable modular solar power system are adjustable to provide support for the portable modular solar power apparatus and to allow for adjustments to an angle of the PV panel 101 held by the lightweight frame 113 with respect to the sunlight. Furthermore, the telescoping legs 116 may be foldable and/or collapsible, allowing the top portion of the lightweight frame 113 to be folded inwardly onto the bottom portion of the lightweight frame 113 (see FIGS. 5B and 5C).

Thus, each of the telescoping legs is adjustable to provide a full range of motion, such that, when the portable modular solar power apparatus is in the operational state, the telescoping legs 116 are folded out and the bottom portion of the lightweight frame 113 is folded out to provide support for the portable modular solar power apparatus (see FIG. 5C). Moreover, when the portable modular solar power apparatus is in the portable state, the two telescoping legs are folded to fit within the lightweight frame 113 and the bottom portion of the lightweight frame 113 is inwardly folded towards the portion of the lightweight frame 113 supporting the PV panel 101, so as to decrease a size and increase mobility of the portable modular solar power apparatus (see FIG. 5B).

The lightweight frame 113, as illustrated, only includes two telescoping legs. However, based on the size of the lightweight frame 113, additional telescoping legs can be included in order to provide sufficient support for the portable modular solar power apparatus. Furthermore, these telescoping legs 116 are also extendable and retractable to further assist the user in adjusting the angle of the PV panel 101 with respect to the sunlight. These features of the telescoping legs 116, such as the folding, the extending and the retracting also provide user of the portable modular solar power system the ability to quickly set up and break down the portable modular solar power system for rapid deployment and extraction.

In addition to the above-described structure of the lightweight frame 113, the lightweight frame 113 can be composed of a light weight material, such as, but not limited to aluminum, and, for example, the fixed range of motion of each of the two telescoping legs can be between 20-65 degrees. Moreover, due to the open-frame structure of the lightweight frame 113, the battery 104 can remain sufficiently cool during charging and while providing the electrical power to the load 106.

The lightweight frame 113 can also be configured to have the PV panel 101 (or multiple PV panels 101) interchangeably mounted thereon, and well as the battery 104 (or multiple batteries 104) interchangeably mounted thereon to meet the various electrical demands of the load 106. Furthermore, multiple portable modular solar power apparatuses can be coupled together, via a coupler (not shown), in order to increase the electrical power output to the load 106.

In addition, the lightweight frame 113 can also accommodate various sizes of PV panels 101 and batteries 104. Moreover, the battery tray 118 of the lightweight structure 113 may be a weather-proof container configured to isolate the battery 104 and/or the charge controller 102 from external weather conditions.

Due to the size and weight of the lightweight frame 113, the modular solar power apparatus could be easily mounted to vehicles or structures, if needed. The lightweight frame 113 may also include an anchor (now shown) for attaching the modular solar power apparatus to the ground, vehicles or structures.

The portable modular solar power apparatus may also include multiple PV panels 101 and multiple batteries 104. Additionally, portable modular solar power system may include multiple portable modular solar power apparatuses (see FIG. 3). For example the portable modular solar power system may include a second portable modular solar power apparatus including a second photovoltaic panel 101, a second battery 104 electrically connected to the second photovoltaic panel 101, and a second lightweight frame configured to have the second photovoltaic panel 101 attached thereto and to house the second battery 104 (see FIGS. 5A-5C).

Applications for the above-described portable modular solar power apparatus may include, but are not limited to, (i) disaster relief, (ii) remote area power, (iii) medical equipment, (iv) lightning damage, (v) ventilation, (vi) military, (vii) remote communication systems, (viii) remote satellite up-link systems, (ix) water purification, (x) water pumping, (xi) computer systems, (xii) stationary refrigeration, (xiii) mobile refrigeration, (xiv) battery charging, and (xv) power tools.

With reference to FIGS. 5A and 5C, the PV panel 101 has a height of 59 inches and a width of 26.1 inches. Furthermore, the telescoping legs 116 and the structure supporting the PV panel 101 are arranged to form a triangular shape, wherein one of the telescoping legs 116 is adjusted to a length of 59 inches. Additionally, one of the telescoping legs 116 provides support for the battery tray 118, which houses the battery 104 (see FIGS. 5B and 5C). The estimated weight of the portable modular solar power apparatus illustrated in FIGS. 5A-5C is 45 pounds. These specific dimensions are only given as an example and should not be limiting to the dimensions of the present invention.

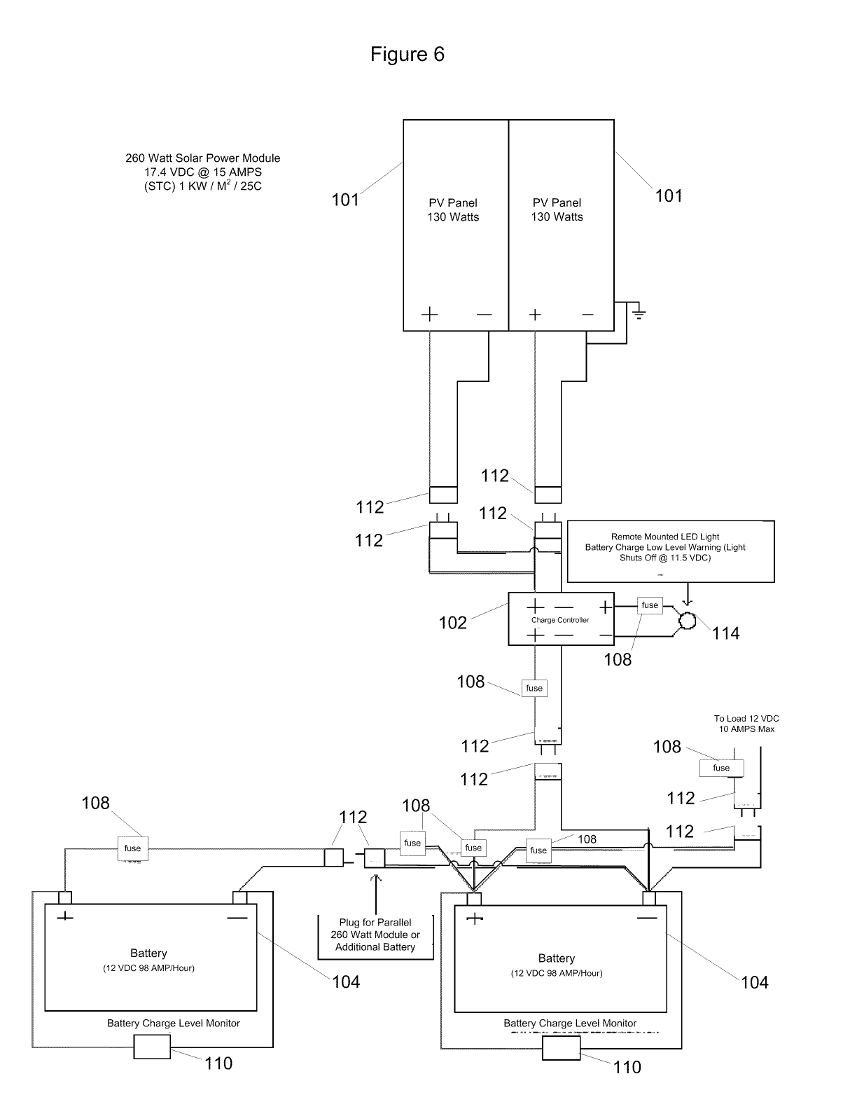

FIG. 6 illustrates a portable modular solar power system including two 130 watt portable modular solar power apparatuses, as illustrated for example in FIG. 4, including two respective 12 VDC batteries connected in parallel to provide a 260 watt solar array rated at 17.4 VDC in accordance with an embodiment of the invention. Specifically, the portable modular solar power system according to FIG. 6 includes two 130 watt PV panels 101, in order to provide a total of 17.4 VDC at 15 amps (STC) 1 KW/M²/25 C. Each of the two 130 watt PV panels is connected to the charge controller 102. The charge controller 102 has the LED light 114 connected thereto with a fuse 108 between the charge controller 102 and the LED light 114.

Moreover, the charge controller 102 is connected to a first battery 104 and a second battery 104, such that a positive terminal of the first battery 104 is connected to a positive terminal of the charge controller 102 and a positive terminal of the load 106. The negative terminal of the first battery 104 is connected to the negative terminal of the load 106 and is connected to a negative terminal of the second battery 104, such that the first and second batteries 104 are connected in parallel. Furthermore, the negative terminal of the first battery 104 is also connected to the negative terminal of the charge controller 102.

Moreover, fuses 108 are located between the positive terminal of the first battery 104 and (i) the positive terminal of the charge controller 102, (ii) the positive terminal of the load 106, and (iii) the positive terminal of the second battery 104. Also, quick connect plugs 112 are provided between the PV panels 101, the charge controller 102, the first battery 104, the second battery 104 and the load 106.

According to this working example, the battery 104 can be a marine grade deep cycle gel cell battery, which provides 12 VDC at 98 Amp/Hour. Additionally, one or more of the above-mentioned 260 watt solar arrays may be connected in parallel to provide, for example, electrical power of 520 watts and 1040 watts.

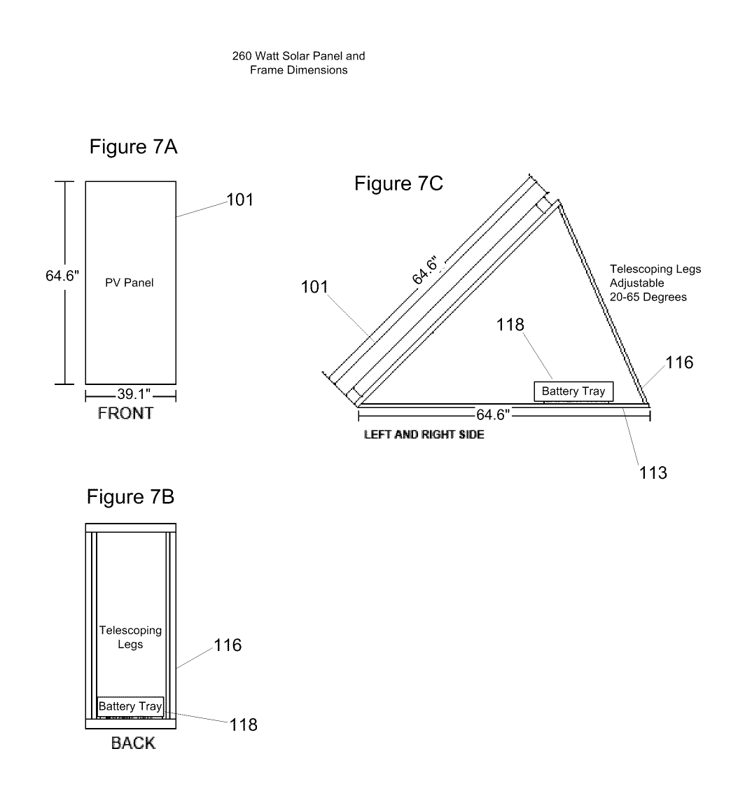

FIGS. 7A-7C illustrate a physical structure of the specific portable modular solar power system including a 230 watt PV panel, as illustrated in FIG. 2, in accordance with an embodiment of the invention. FIG. 7A illustrates the front of the portable modular solar power apparatus, FIG. 7B illustrates the back of the portable modular solar power apparatus, when the portable modular solar power apparatus is in a portable state, and FIG. 7C illustrates the left and/or right sides of the portable modular solar power apparatus, when the portable modular solar power apparatus is in a operational state.

Specifically, as illustrated in FIGS. 7A and 7C, the PV panel 101 has a height of 64.6 inches and a width of 39.1 inches. Furthermore, the telescoping legs 116 and the structure supporting the PV panel 101 are arranged to form a triangular shape, wherein one of the telescoping legs 116 is adjusted to a length of 64.5 inches. Additionally, one of the telescoping legs 116 provides support for the battery tray 118, which houses the battery 104 (see FIGS. 7B and 7C). The estimated weight of the portable modular solar power apparatus illustrated in FIGS. 7A-7C is 59 pounds.

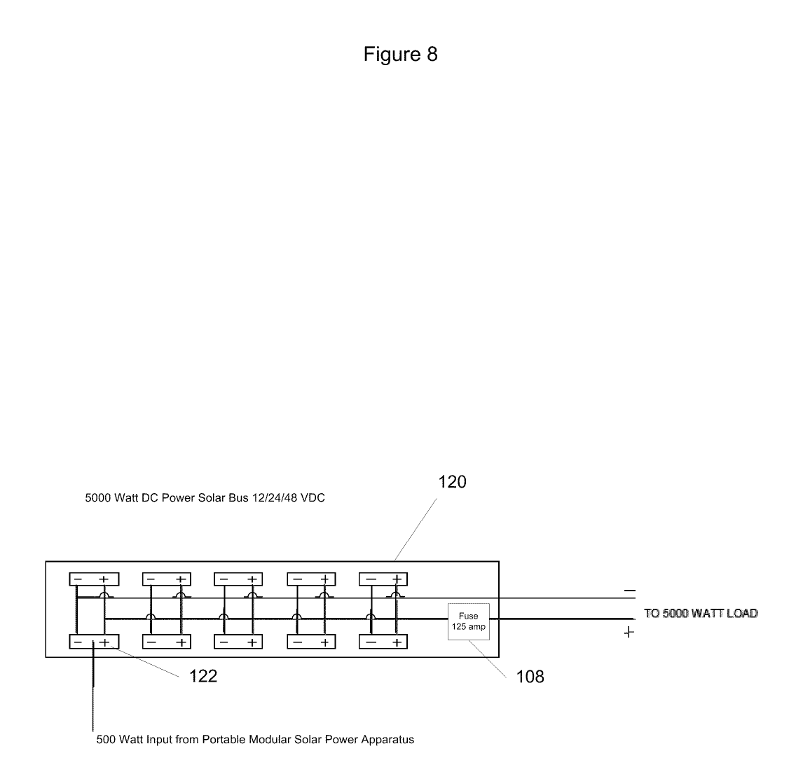

FIG. 8 illustrates a 5000 watt DC power solar bus 120 providing 12/24/48 VDC to an electrical load 106. The power solar bus 120 includes multiple connectors 122 connected in parallel. Each of the connectors 122 can be connected to a portable modular solar power apparatus 101 providing, for example, 500 watts of electrical power. Accordingly, as illustrated in FIG. 8, if the power solar bus 120 includes 10 connectors 122, each connected to a portable modular solar power apparatus 101 providing 500 watts, then the power solar bus 120 could provide 5000 watts to an electrical load 106. Further, as illustrated in FIG. 8, a fuse 108, rated at 125 amps for example, can be connected between a connector 122 and a positive terminal of the electrical load 106.

Additionally, it should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claim.

1. A portable modular solar power apparatus for converting sunlight to electrical energy and providing electrical power to a load, the portable modular solar power apparatus comprising:
a photovoltaic panel configured to convert the sunlight to the electrical energy;
a battery electrically connected to the photovoltaic panel thereby receiving an electrical charge from the photovoltaic panel, and configured to provide the electrical power to the load electrically connected to the battery; and
a lightweight frame configured to have the photovoltaic panel removeably attached thereto and to house the battery, the lightweight frame including:
a battery tray configured to support the battery and to provide self ballasting for the portable modular solar power apparatus using the battery; and
at least two adjustable telescoping legs configured to provide support for the portable modular solar power apparatus and to allow for adjustments to an angle of the photovoltaic panel with respect to receipt of the sunlight.

2. The portable modular solar power apparatus of claim 1, wherein each of the at least two telescoping legs is foldable to provide a fixed range of motion, such that, when the portable modular solar power apparatus is in an operational state, the at least two adjustable telescoping legs are folded out to provide support for the portable modular solar power apparatus, and when the portable modular solar power apparatus is in a portable state, the at least two adjustable telescoping legs are folded in to decrease a size and increase mobility of the portable modular solar power apparatus.

3. The portable modular solar power apparatus of claim 2, wherein the fixed range of motion of each of the at least two telescoping legs is 20-65 degrees.

4. The portable modular solar power apparatus of claim 1, further comprising a charge controller configured to control the electrical charge of the battery by receiving the electrical energy from the photovoltaic panel and by providing the electrical charge to the battery.

5. The portable modular solar power apparatus of claim 1, wherein the portable modular solar power apparatus is configured to provide the electrical power to a direct current electrical load, such that the electrical power provides at least one of 12 volts, 24 volts and 48 volts to the direct current electrical load.

6. The portable modular solar power apparatus of claim 2,
wherein the lightweight frame comprises:
a top portion configured to attach to the photovoltaic panel; and
a bottom portion configured to attach to the battery tray, and
wherein the top portion is foldable onto the bottom portion when the at least two adjustable telescoping legs are folded in while in the portable state.

7. The portable modular solar power apparatus of claim 1, wherein the battery tray is a weather-proof container configured to isolate the battery from weather conditions.

8. The portable modular solar power apparatus of claim 1,
wherein the photovoltaic panel electrically connects to the battery via a quick connect plug, and
wherein the battery electrically connects to the load via a quick connect plug.

9. The portable modular solar power apparatus of claim 1, wherein the lightweight frame is configured to have a plurality of photovoltaic panels attached thereto, including the photovoltaic panel, and to house a plurality of batteries, including the battery.

10. A portable modular solar power system for converting sunlight to electrical energy and providing electrical power, the portable modular solar power system comprising:
a load configured to receive the electrical power; and
a portable modular solar power apparatus including:
a photovoltaic panel configured to convert the sunlight to the electrical energy;
a battery electrically connected to the photovoltaic panel thereby receiving an electrical charge from the photovoltaic panel, and configured to provide the electrical power to the load electrically connected to the battery; and
a lightweight frame configured to have the photovoltaic panel removeably attached thereto and to house the battery, the lightweight frame including:
a battery tray configured to support the battery and to provide self ballasting for the portable modular solar power apparatus using the battery; and
at least two adjustable telescoping legs configured to provide support for the portable modular solar power apparatus and to allow for adjustments to an angle of the photovoltaic panel with respect to receipt of the sunlight.

11. The portable modular solar power system of claim 10, wherein each of the at least two telescoping legs is foldable to provide a fixed range of motion, such that, when the portable modular solar power apparatus is in an operational state, the at least two adjustable telescoping legs are folded out to provide support for the portable modular solar power apparatus, and when the portable modular solar power apparatus is in a portable state, the at least two adjustable telescoping legs are folded in to decrease a size and increase mobility of the portable modular solar power apparatus.

12. The portable modular solar power system of claim 10, further comprising a charge controller configured to control the electrical charge of the battery by receiving the electrical energy from the photovoltaic panel and by providing the electrical charge to the battery.

13. The portable modular solar power system of claim 10, wherein the portable modular solar power apparatus is configured to provide the electrical power to a direct current electrical load, such that the electrical power provides at least one of 12 volts, 24 volts and 48 volts to the direct current electrical load.

14. The portable modular solar power system of claim 11,
wherein the lightweight frame comprises:
a top portion configured to attach to the photovoltaic panel; and
a bottom portion configured to attach to the battery tray, and
wherein the top portion is foldable onto the bottom portion when the at least two adjustable telescoping legs are folded in while in the portable state.

15. The portable modular solar power system of claim 10, wherein the battery tray is a weather-proof container configured to isolate the battery from weather conditions.

16. The portable modular solar power system of claim 10,
wherein the photovoltaic panel electrically connects to the battery via a quick connect plug, and
wherein the battery electrically connects to the load via a quick connect plug.

17. The portable modular solar power system of claim 10, further comprising a second portable modular solar power apparatus including:
a second photovoltaic panel configured to convert the sunlight to the electrical energy;
a second battery electrically connected to the second photovoltaic panel thereby receiving an electrical charge from the second photovoltaic panel, and configured to provide the electrical power to the load; and
a second lightweight frame configured to have the second photovoltaic panel removeably attached thereto and to house the second battery, the second lightweight frame including:
a second battery tray configured to support the second battery and to provide self ballasting for the second portable modular solar power apparatus using the second battery; and
at least two adjustable telescoping legs configured to provide support for the second portable modular solar power apparatus and to allow for adjustments to an angle of the second photovoltaic panel with respect to receipt of the sunlight.

18. The portable modular solar power system of claim 17, wherein the battery and the second battery are connected in parallel, so as to increase a current of the electrical power provided to the load.

19. The portable modular solar power system of claim 17, wherein the battery and the second battery are connected in series, so as to increase a voltage of the electrical power provided to the load.

20. A method of assembling and using a portable modular solar power system for converting sunlight to electrical energy and providing electrical power to a load,
wherein the portable modular solar power system includes:
the load configured to receive the electrical power; and
a portable modular solar power apparatus including:
a photovoltaic panel configured to convert the sunlight to the electrical energy;
a battery configured to receive an electrical charge from the photovoltaic panel, and to provide the electrical power to the load; and
a lightweight frame including a battery tray configured to support the battery, and including at least two adjustable telescoping legs configured to provide support for the portable modular solar power apparatus and to allow for adjustments to an angle of the photovoltaic panel with respect to receipt of the sunlight, and
wherein the method comprises:
modularly connecting the photovoltaic panel to a surface of the lightweight frame;
placing the battery on the battery tray of the lightweight frame, so as to provide self ballasting for the portable modular power apparatus using the battery;
electrically connecting the photovoltaic panel and the battery allowing the battery to receive the electrical charge from the photovoltaic panel;
electrically connecting the load to the battery allowing the load to receive the electrical power from the battery; and
adjusting a length of the at least two adjustable telescoping legs, so as to provide the support for the portable modular solar power apparatus and to adjust the angle of the photovoltaic panel with respect to the receipt of the sunlight.
